(19) United States
(12) Patent Application Publication
(10) Pub. No.: US 2011/0062487 A1
(43) Pub. Date: Mar. 17, 2011

(54) SEMICONDUCTOR LIGHT EMITTING DEVICE

(75) Inventor: Ji Won Oh, Gyeonggi-do (KR)

(73) Assignee: EPIVALLEY CO., LTD., Gyungbuk (KR)

(21) Appl. No.: 12/992,687

(22) PCT Filed: Sep. 19, 2008
(86) PCT No.: PCT/KR08/05532

§ 371 Date: Nov. 15, 2010

(30) Foreign Application Priority Data
May 15, 2008 (KR) 10-2008-0045185

(51) Int. Cl. H01L 33/38

(52) U.S. Cl. 257/99; 257/E33.062

(57) ABSTRACT

The present disclosure relates to a semiconductor light emitting device, the semiconductor light emitting device comprising: a plurality of openings positioned between first electrode and second electrode, the plurality of openings defining a first opening region for suppressing current flow between the first electrode and the second electrode and a second opening region for relatively less suppressing current flow than the first opening region.

### TECHNICAL FIELD

The present disclosure relates to a semiconductor light emitting device, and more particularly, to a semiconductor light emitting device having an electrode structure for improving current spreading.

Here, the semiconductor light emitting device means a optical semiconductor device generating light by recombination of electrons and holes. A III-nitride semiconductor light emitting device is one example of the semiconductor light emitting device. The III-nitride semiconductor light emitting device includes a compound semiconductor layer composed of Al(x)Ga(y)In(1-x-y)N (0≦x≦1,0≦y≦1,0≦x+y≦1). A GaAs semiconductor light emitting device generating red light is another example of a III-nitride semiconductor light emitting device.

### BACKGROUND ART

FIG. 1 is a view illustrating one example of a conventional III-nitride semiconductor light emitting device. The III-nitride semiconductor light emitting device includes a substrate 100, a buffer layer 200 grown on the substrate 100, an n-type nitride semiconductor layer 300 grown on the buffer layer 200, an active layer 400 grown on the n-type nitride semiconductor layer 300, a p-type nitride semiconductor layer 500 grown on the active layer 400, a p-side electrode 600 formed on the p-type nitride semiconductor layer 500, a p-side bonding pad 700 formed on the p-side electrode 600, and an n-side electrode 800 formed on the n-type nitride semiconductor layer exposed by mesa-etching the p-type nitride semiconductor layer 500 and the active layer 400.

In the case of the substrate 100, a GaN substrate can be used as a homo-substrate, and a sapphire substrate, a SiC substrate or a Si substrate can be used as a hetero-substrate. However, any type of substrate that can grow a nitride semiconductor layer thereon can be employed. In the case that the SiC substrate is used, the n-side electrode 800 can be formed on the side to of the SiC substrate.

The nitride semiconductor layers epitaxially grown on the substrate 100 are grown usually by metal organic chemical vapor deposition (MOCVD).

The buffer layer 200 serves to overcome differences in lattice constant and thermal expansion coefficient between the hetero-substrate 100 and the is nitride semiconductor layers. U.S. Pat. No. 5,122,845 discloses a technique of growing an AlN buffer layer with a thickness of 100 to 500 Å on a sapphire substrate at 380 to 800° C. In addition, U.S. Pat. No. 5,290,393 discloses a technique of growing an Al₍ₓ₎Ga₍₁₋ₓ₎N (0≦x<1) buffer layer with a thickness of 10 to 5000 Å on a sapphire substrate at 200 to 900° C. Moreover, PCT Publication No. WO/05/053042 discloses a technique of growing a SiC buffer layer (seed layer) at 600 to 990° C., and growing an In₍ₓ₎Ga₍₁₋ₓ₎N (0<x≦1) thereon. Preferably, it is provided with an undoped GaN layer on the buffer layer 200, prior to growth of the n-type nitride semiconductor layer 300.

In the n-type nitride semiconductor layer 300, at least the n-side electrode 800 formed region (n-type contact layer) is doped with a dopant. Preferably, the n-type contact layer is made of GaN and doped with Si. U.S. Pat. No. 5,733,796 discloses a technique of doping an n-type contact layer at a target doping concentration by adjusting the mixture ratio of Si and other source materials.

The active layer 400 generates light quanta (light) by recombination of electrons and holes. Normally, the active layer 400 contains In₍ₓ₎Ga₍₁₋ₓ₎N (0<x≦1) and has single or multi-quantum well layers.

The p-type nitride semiconductor layer 500 is doped with an appropriate dopant such as Mg, and has p-type conductivity by an activation process. U.S. Pat. No. 5,247,533 discloses a technique of activating a p-type nitride semiconductor layer by electron beam irradiation. Moreover, U.S. Pat. No. 5,306,662 discloses a technique of activating a p-type nitride semiconductor layer by annealing over 400° C. PCT Publication No. WO/05/022655 discloses a technique of endowing a p-type nitride semiconductor layer with p-type conductivity without an activation process, by using ammonia and a hydrazine-based source material together as a nitrogen precursor for growing the p-type nitride semiconductor layer.

The p-side electrode 600 is provided to facilitate current supply to the p-type nitride semiconductor layer 500. U.S. Pat. No. 5,563,422 discloses a technique associated with a light transmitting electrode composed of Ni and Au and formed almost on the entire surface of the p-type nitride semiconductor layer 500 and in ohmic-contact with the p-type nitride semiconductor layer 500. In addition, U.S. Pat. No. 6,515,306 discloses a technique of forming an n-type superlattice layer on a p-type nitride semiconductor layer, and forming a light transmitting electrode made of ITO thereon.

Meanwhile, the p-side electrode 600 can be formed thick not to transmit but to reflect light toward the substrate 100. This technique is called a flip chip technique. U.S. Pat. No. 6,194,743 discloses a technique associated with an electrode structure including an Ag layer with a thickness over 20 nm, a diffusion barrier layer covering the Ag layer, and a bonding layer containing Au and AI, and covering the diffusion barrier layer.

The p-side bonding pad 700 and the n-side electrode 800 are provided for current supply and external wire bonding. U.S. Pat. No. 5,563,422 discloses a technique of forming an n-side electrode with Ti and Al.

In the meantime, the n-type nitride semiconductor layer 300 or the p-type nitride semiconductor layer 500 can be constructed as single or plural layers. Recently, a technology of manufacturing vertical light emitting devices is introduced by separating the substrate 100 from the nitride semiconductor layers using laser technique or wet etching.

FIG. 2 is a view illustrating one example of a light emitting device disclosed in U.S. Pat. No. 5,563,422. A p-side bonding pad 700 and an n-side electrode 800 are diagonally positioned at the corners of the light emitting device to keep up the furthest distance from each other so that current spreading can be improved. However, there is a problem that the current is concentrated on a central portion of the light emitting device.

FIGS. 3 and 4 are views illustrating one example of an electrode structure disclosed in U.S. Pat. No. 6,445,007, particularly, a technology of forming a plurality of holes 900 in a p-side electrode 600 so as to secure a predetermined current spreading distance between a p-side bonding pad 700 and an n-side electrode 800. Explanations of elements with same reference numerals will be omitted.

FIGS. 5 and 6 are views illustrating one example of a light emitting device disclosed in U.S. Pat. No. 6,781,147, particularly, a technology to form a trench 910 reaching to an n-type nitride semiconductor layer 300 in order to prevent current concentration from occurring between a p-side bonding pad 700 and an n-side electrode 800. Elements with same reference numerals will not be explained.

However, since the light emitting device merely has the plurality of holes 900 or the trench 910 for current spreading between the p-side bonding pad 700 and the n-side electrode 800, light emission may excessively be suppressed by them at the central portion of the light emitting device.

FIGS. 7 and 8 are views illustrating one example of a light emitting device disclosed in Japanese Patent Publication No. 2001-024222, particularly, a technology of forming a plurality of trenches 920 over the entire light emitting device so as to only improve external quantum efficiency. In this case, since the same resistance is applied to the entire light emitting device, a current spreading problem still exists as in the light emitting device of FIG. 2. Explanations of elements with same reference numerals will be omitted.

### DISCLOSURE

### Technical Problem

Accordingly, the present disclosure has been made to solve the above-described shortcomings occurring in the prior art, and an object of the present disclosure is to provide a semiconductor light emitting device which can solve the foregoing problems.

Another object of the present disclosure is to provide a semiconductor light emitting device which can improve current spreading.

Also, another object of the present disclosure is to provide a semiconductor light emitting device which can facilitate current spreading at a central portion thereof.

### Technical Solution

This section provides a general summary of the disclosure and is not a comprehensive disclosure of its full scope or all of its features.

According to one aspect of the present disclosure, there is provided a semiconductor light emitting device comprising: a plurality of semiconductor layers including a first semiconductor layer with first conductivity, a second semiconductor layer with second conductivity different from the first conductivity, and an active layer positioned between the first semiconductor layer and the second semiconductor layer to generate light by recombination of electrons and holes; a first electrode electrically contacting the first semiconductor layer exposed by removing the active layer; a second electrode electrically contacting the second semiconductor layer; and a plurality of openings positioned between the first electrode and the second electrode, the plurality of openings defining a first opening region for suppressing current flow between the first electrode and the second electrode and a second opening region for relatively less suppressing current flow than the first opening region.

### ADVANTAGEOUS EFFECTS

In accordance with a semiconductor light emitting device of the present disclosure, current can be easily spread throughout the semiconductor light emitting device.

Also, in accordance with a semiconductor light emitting device of the present disclosure, current can be easily spread at a central portion thereof.

### DESCRIPTION OF DRAWINGS

FIG. 1 is a view illustrating one example of a conventional III-nitride semiconductor light emitting device.

FIG. 2 is a view illustrating one example of a light emitting device disclosed in U.S. Pat. No. 5,563,422.

FIGS. 3 and 4 are views illustrating one example of an electrode structure disclosed in U.S. Pat. No. 6,445,007.

FIGS. 5 and 6 are views illustrating one example of a light emitting device disclosed in U.S. Pat. No. 6,781,147.

FIGS. 7 and 8 are views illustrating one example of a light emitting device disclosed in Japanese Laid-Open Patent 2001-024222.

FIGS. 9 and 10 are views illustrating one example of a semiconductor light emitting device according to the present disclosure.

FIG. 11 is a view illustrating another example of a semiconductor light emitting device according to the present disclosure.

FIG. 12 is a view illustrating a further example of a semiconductor light emitting device according to the present disclosure.

FIG. 13 is a view illustrating a furthermore example of a semiconductor light emitting device according to the present disclosure.

FIG. 14 is a view illustrating a still furthermore example of a semiconductor light emitting device according to the present disclosure.

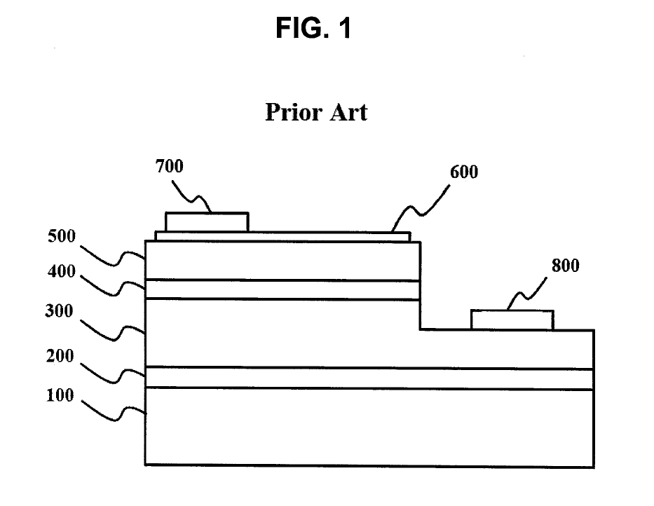

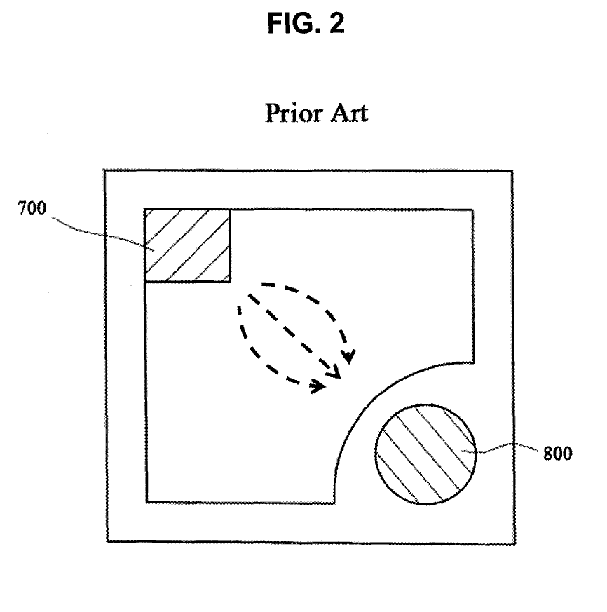

### MODE FOR INVENTION

The present disclosure will now be described in detail with reference to the accompanying drawings.

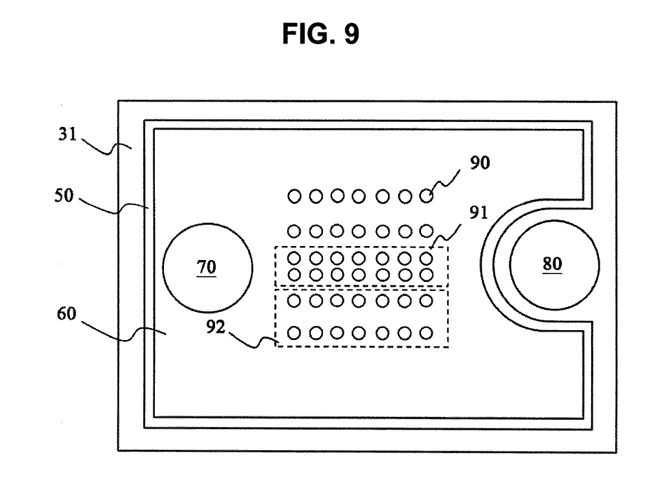

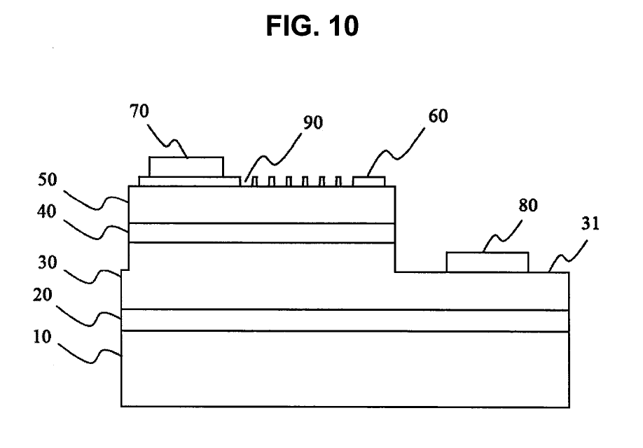

FIGS. 9 and 10 are views illustrating one example of a semiconductor light emitting device according to the present disclosure. The semiconductor light emitting device includes a sapphire substrate 10, a buffer layer 20 grown on the sapphire substrate 10, an n-type nitride semiconductor layer 30 grown on the buffer layer 20, an active layer 40 grown on the n-type nitride semiconductor layer 30, a p-type nitride semiconductor layer 50 grown on the active layer 40, a p-side light transmitting electrode 60 formed on the p-type nitride semiconductor layer 50, a p-side bonding pad 70 formed on the p-side light transmitting electrode 60, and an n-side electrode 80 formed on a region 31 of the n-type nitride semiconductor layer 30 exposed by etching the p-type nitride semiconductor layer 50 and the active layer 40.

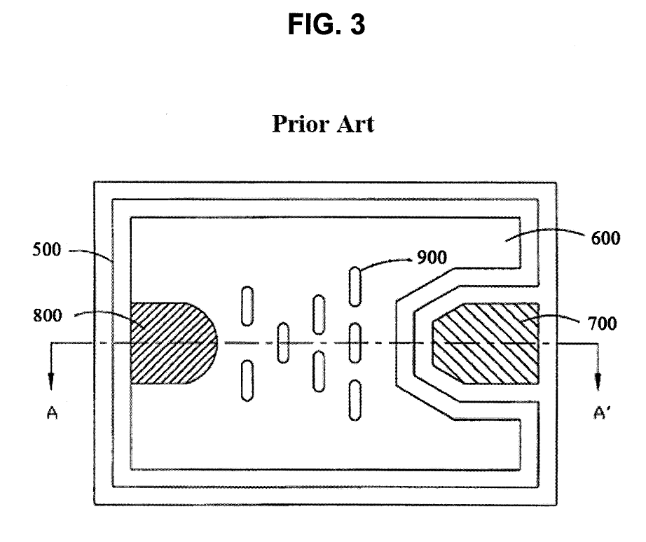

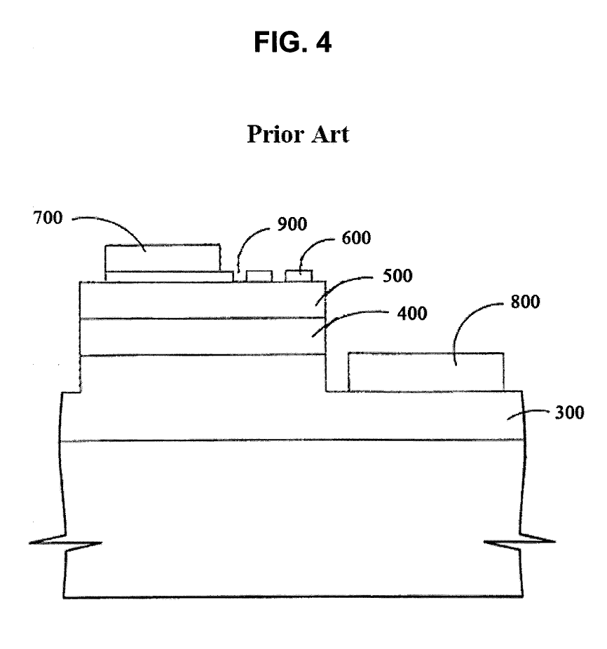

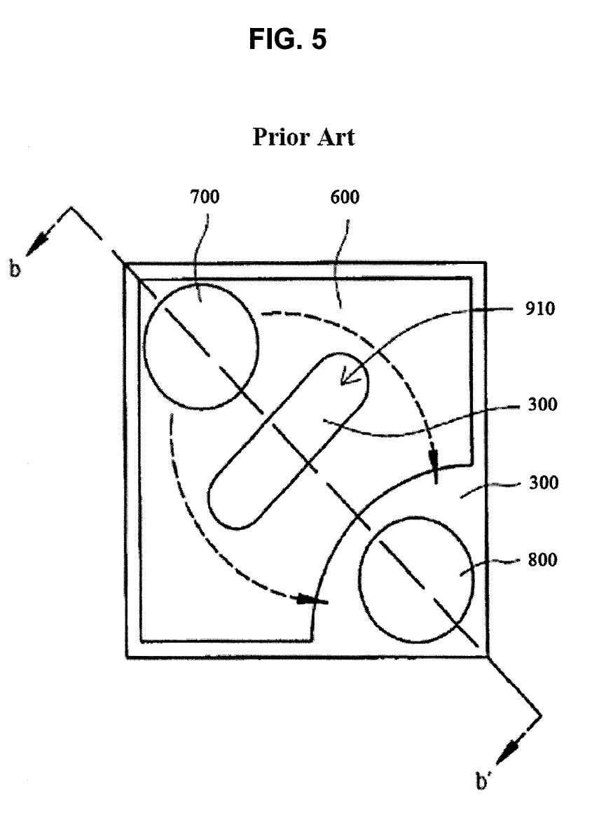

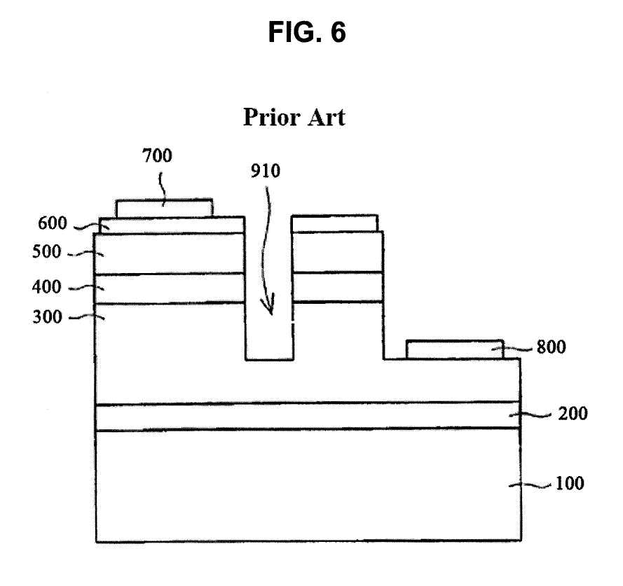

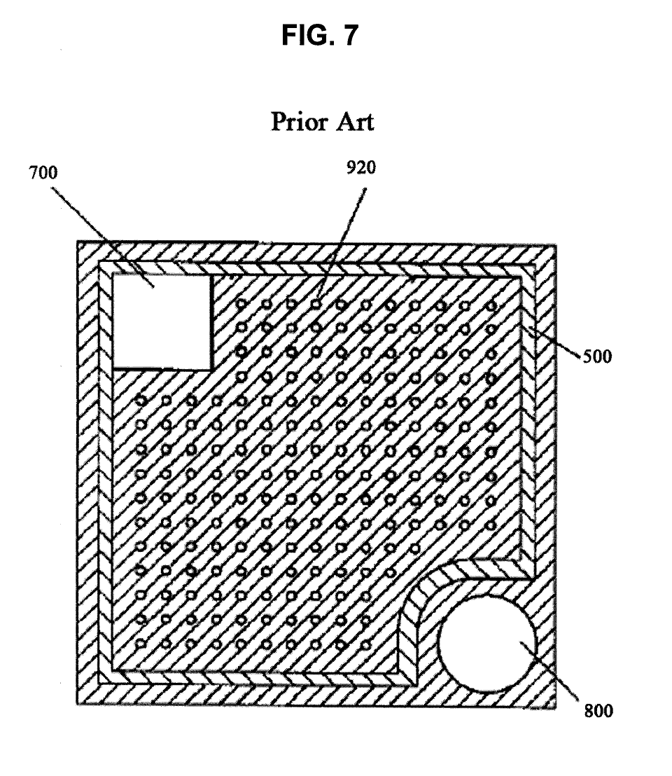

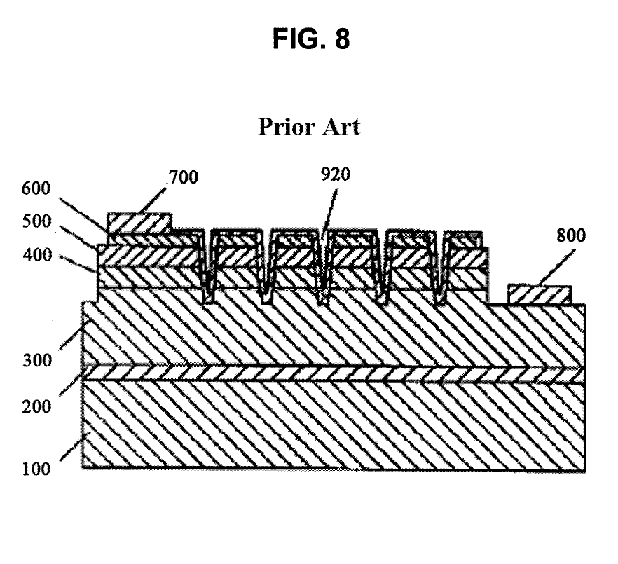

The p-side light transmitting electrode 60 includes a plurality of openings 90. The plurality of openings 90 have a first opening region 91 and a second opening region 92 between the n-side electrode 80 and the p-side bonding pad 70 not only not to excessively suppress current flow at a central portion of the light emitting device but also to facilitate current flow over the entire light emitting device. The plurality of openings 90 in the first opening region 91 are densely formed and the plurality of openings 90 in the second opening region 92 are sparsely formed, so as to relatively less suppress current flow in the second opening region 92 than in the first opening region 91. Therefore, resistance of the first opening region 91 is higher than that of the second opening region 92, so that current concentration in the first opening region 91 can be reduced. In the contrast with the light emitting device of FIG. 3 or 5, the light emitting device does not excessively suppress current flow at the central portion thereof. As a result, current spreading can be smooth and uniform over the entire light emitting device.

The plurality of openins 90 formed in the p-side transmitting electrode 60 can function not only to control resistance of the p-side light transmitting electrode 60 but also to be a window through which light blocked by the p-side light transmitting electrode 60 goes.

The plurality of openings 90 can be formed by a mask pattern during the deposition of the p-side light transmitting electrode 60, or by etching after the formation of the p-side light transmitting electrode 60. There are no special limitations on the forming methods. The pattern can be formed by means of photolithography, nano-imprit or the like.

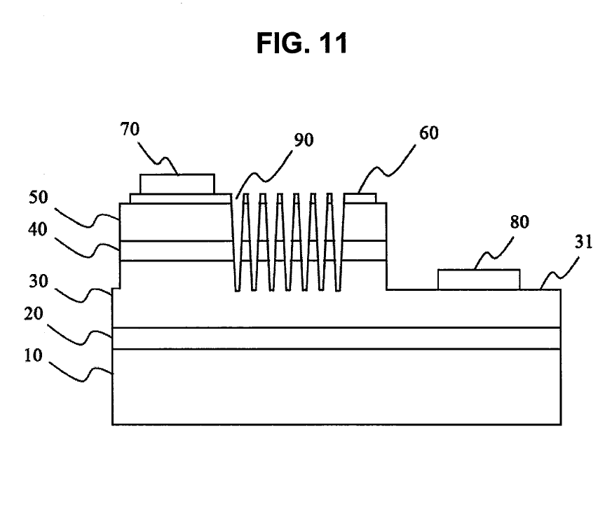

FIG. 11 is a view illustrating another example of a semiconductor light emitting device according to the present disclosure. In contrast with the semiconductor light emitting device of FIG. 10, a plurality of openings 90 are extended to an n-type nitride semiconductor layer 30 so as to make trenche 90.

The trench 90 can have a function to help light generated in an active layer 40 be extracted from the inside of the semiconductor light emitting device to the outside. Besides, the trench 90 can effectively cool the device and this function is particularly important to a device with a large size. Elements with same reference numerals will not be explained.

There are no special limitations on forming the trenches. The trenches may be formed by etching after the deposition of a p-side light transmitting electrode 60, and may have a size of a photonic crystal order. Meanwhile, the p-side light transmitting electrode 60 may be deposited after the formation of the trenches. Preferably, the trenches are formed with a exposed region 31 of an n-type nitride semiconductor layer 30.

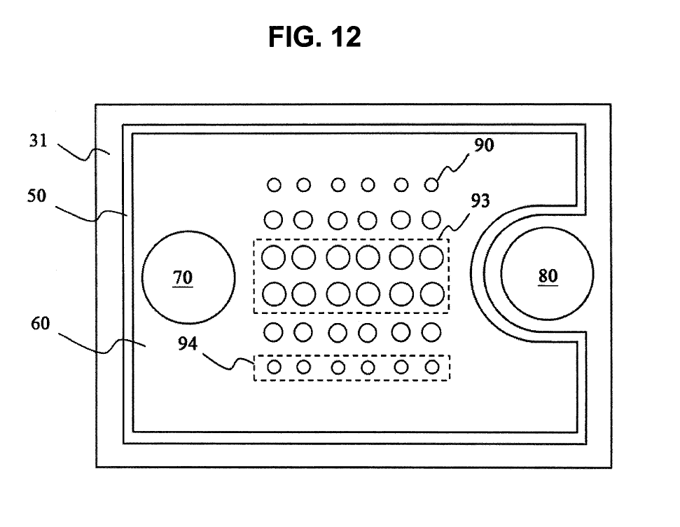

FIG. 12 is a view illustrating a further example of a semiconductor light emitting device according to the present disclosure. A plurality of openings 90 have a first opening region 93 and a second opening region 94 to be formed by regulating the size of the plurality of openings 90. The plurality of openings 90 in the first opening region 93 are formed to be larger than those in the second opening region 94, so that resistance of the first opening region 93 is higher than that of the second opening region 94. Explanations of elements with same reference numerals will be omitted.

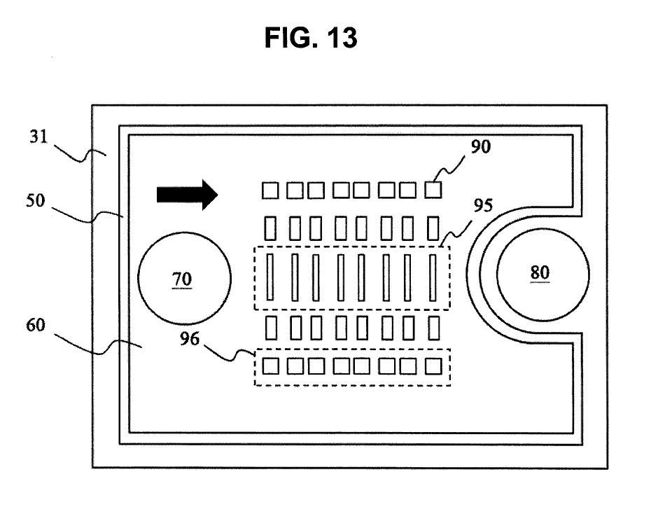

FIG. 13 is a view illustrating a furthermore example of a semiconductor light emitting device according to the present disclosure. A plurality of openings 90 have a first opening region 95 and a second opening region 96 to be formed by regulating the length, which are facing current flow (arrow direction), of the plurality of openings 90. In contrast with regulating the size, even though the size is the same, i.e. the area is the same (i.e. the resistance is the same), current spreading can be facilitated over the entire light emitting device by forming a barrier against the current flowing direction. Elements with same reference numerals will not be explained.

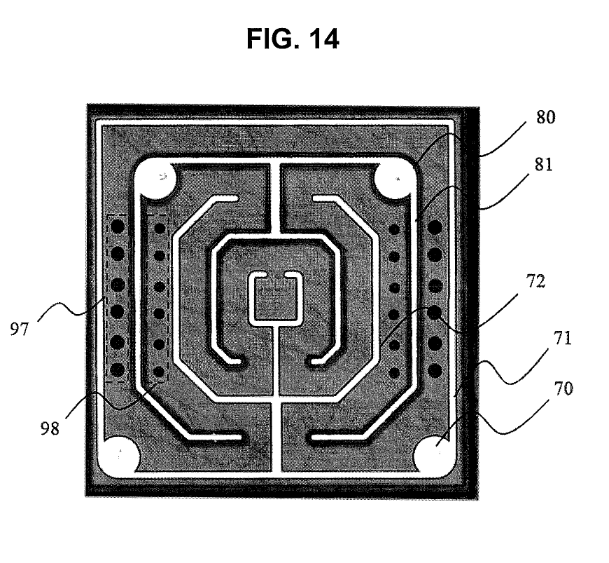

FIG. 14 is a view illustrating a still furthermore example of a semiconductor light emitting device according to the present disclosure. The semiconductor light emitting device has branch electrodes 71 and 72 and a branch electrode 81. The branch electrodes 71 and 72 are extended from a p-side bonding pad 70. The branch electrode 81 is extended from an n-side electrode 80 and alternatevely positioned with the branch electrodes 71 and 72. In this case, current may be concentrated between the p-side bonding pad 70 and the n-side electrode 80, i.e., between the branch electrode 71 and the branch electrode 81. To solve this problem, a first opening region 97 is positioned between the branch electrode 71 and the branch electrode 81, and a second opening region 98 is positioned between the branch electrode 81 and the branch electrode 72.

Various embodiments of the present disclosure will now be described.

(1) The semiconductor light emitting device comprises a third electrode positioned between the second semiconductor layer and the second electrode, the plurality of openings being formed therein.

(2) The semiconductor light emitting device, wherein the plurality of openings extend to the plurality of semiconductor layers.

(3) The semiconductor light emitting device, wherein the density of the openings of the first opening region is higher than that of the second opening region.

(4) The semiconductor light emitting device, wherein the size of the openings of the first opening region is larger than that of the second opening region.

(5) The semiconductor light emitting device, wherein the length of openings of the first opening region which faces current flow is longer than that of the second opening region which faces current flow.

(6) The semiconductor light emitting device, wherein the first opening region and the second opening region are different in at least one of the density, size of the openings and the length of the openings which faces current flow.

(7) The semiconductor light emitting device, comprising a third electrode positioned between the second semiconductor layer and the second electrode, wherein the plurality of openings are formed to pass through at least the third electrode.

(8) The semiconductor light emitting device, comprising: a first branch electrode extended from the first electrode; and a second branch electrode extended from the second electrode, and positioned alternately with the first branch electrode to define a first region and a second region, wherein the first opening region is positioned in the first region, and the second opening region is positioned in the second region.

(9) The semiconductor light emitting device, which is a III-nitride semiconductor light emitting device.

1. A semiconductor light emitting device, comprising:
a plurality of semiconductor layers including a first semiconductor layer with first conductivity, a second semiconductor layer with second conductivity different from the first conductivity, and an active layer positioned between the first semiconductor layer and the second semiconductor layer to generate light by recombination of electrons and holes;
a first electrode electrically contacting the first semiconductor layer exposed by removing the active layer;
a second electrode electrically contacting the second semiconductor layer; and
a plurality of openings positioned between the first electrode and the second electrode, the plurality of openings defining a first opening region for suppressing current flow between the first electrode and the second electrode and a second opening region for relatively less suppressing current flow than the first opening region.

2. The semiconductor light emitting device of claim 1, comprising a third electrode positioned between the second semiconductor layer and the second electrode, the plurality of openings being formed in the third electrode.

3. The semiconductor light emitting device of claim 1, wherein the plurality of openings extend to the plurality of semiconductor layers.

4. The semiconductor light emitting device of claim 1, wherein the density of the openings of the first opening region is higher than that of the second opening region.

5. The semiconductor light emitting device of claim 1, wherein the size of the openings of the first opening region is larger than that of the second opening region.

6. The semiconductor light emitting device of claim 1, wherein the length of openings of the first opening region which faces current flow is longer than that of the second opening region which faces current flow.

7. The semiconductor light emitting device of claim 1, wherein the first opening region and the second opening region are different in at least one of the density, size of the openings and the length of the openings which faces current flow.

8. The semiconductor light emitting device of claim 7, comprising a third electrode positioned between the second semiconductor layer and the second electrode, wherein the plurality of openings are formed to pass through at least the third electrode.

9. The semiconductor light emitting device of claim 7, comprising:
a first branch electrode extended from the first electrode; and
a second branch electrode extended from the second electrode, and positioned alternately with the first branch electrode to define a first region and a second region,
wherein the first opening region is positioned in the first region, and the second opening region is positioned in the second region.

10. The semiconductor light emitting device of claim 8, which is a Ill-nitride semiconductor light emitting device.
